(19) United States
(12) Patent Application Publication
(10) Pub. No.: US 2015/0056552 A1
(43) Pub. Date: Feb. 26, 2015

(54) Method of Processing a Photosensitive Structure

(71) Applicant: Conductive inkjet Technology Limited, Yorkshire (GB)

(72) Inventors: Philip Gareth Bentley, Cambridgeshire (GB); Jonathon Brooks, Cambridgeshire (GB); Martyn Robinson, Cambridgeshire (GB)

(73) Assignee: CONDUCTIVE INKJET TECHNOLOGY LIMITED, Yorkshire (GB)

(21) Appl. No.: 14/378,173

(22) PCT Filed: Jan. 16, 2013
(86) PCT No.: PCT/GB2013/050087

§ 371 Date: Aug. 12, 2014

(30) Foreign Application Priority Data
Feb. 27, 2012 (GB) 1203344.5

(51) Int. Cl. G03F 7/09; G03F 7/20; G03F 7/16

(52) U.S. Cl. CPC G03F 7/092; G03F 7/16; G03F 7/20
USPC 430/270.1; 430/325

(57) ABSTRACT

The invention provides a method of applying a coating material to a photosensitive material to form a surface coating, wherein the photosensitive material, before or after curing, and the surface coating are soluble in a first liquid, the method comprising applying the coating material as a dispersion in a second liquid in which the photosensitive material is insoluble. By applying the coating material as a dispersion in a liquid in which the photosensitive material is insoluble, the photosensitive material is not disrupted.

### FIELD OF THE INVENTION

This invention relates to photosensitive structures that are useful e.g. in photopatterning, for example by the process of photolithography.

### BACKGROUND TO THE INVENTION

Photolithography has been widely used for patterning structures in the fields of electronics and microelectronics. Printed circuit boards for the electronics industry and silicon integrated circuits have been produced by the process of photolithography for many decades. In the process of photolithography, a photosensitive material is selectively exposed in pattern wise manner to electromagnetic radiation (usually ultraviolet (UV), visible, infra red, electron beam or a combination thereof) of a wavelength which causes a physical or chemical change in the material such that it can be used to form a pattern. Typically, the exposure causes the material to become more or less soluble, effectively changing the state of the material from soluble to insoluble (or vice versa) with respect to a particular solvent or developing medium. The solvent or developing medium can then be used to remove either the exposed or unexposed regions of the photosensitive material. Commonly, such materials will be referred to as photoresists. Once exposed to the patterning radiation and then developed, the resulting patterned resist can be used as a barrier to protect certain areas of the underlying material from chemical or physical attack from a range of wet or dry etching species. For example, a photoresist may be coated on top of a copper clad epoxy glass board, for producing printed circuits. Regions of this photoresist which are exposed to UV light can become soluble in a particular developer solution. Once exposed and developed, the copper metal will be exposed only in areas which were previously exposed to UV light. If the board is now immersed in a solution of ferric chloride, the exposed regions of copper will be dissolved away, leaving the regions which are still coated in resist. Subsequent removal of the resist will leave the desired pattern of copper on the board. Typically this would be in the pattern of a series of tracks and pads onto which electronics devices may be mounted and connected to each other.

Photoresist materials are typically used for a subtractive patterning process, i.e. those where unwanted material is removed and the required material is protected by the resist, but photolithography may also be used for additive processes.

### SUMMARY OF THE INVENTION

In one aspect, the invention provides a method of applying a coating material to a photosensitive material to form a surface coating, wherein the photosensitive material (before or after curing) and the surface coating are soluble in a first liquid, the method comprising applying the coating material as a dispersion in a second liquid in which the photosensitive material is insoluble.

By applying the coating material as a dispersion in a liquid in which the photosensitive material is insoluble, the photosensitive material is not disrupted. The invention thus enables application of coating materials that are only soluble in liquids that are also solvents for the photosensitive material (as is the case with many coating materials and photosensitive materials), where application from solution would disrupt the photosensitive material. The invention thus facilitates use of a wide range of coating materials.

In a further aspect, the invention provides a photosensitive structure, particularly a photopatternable structure, comprising a photosensitive material having a surface coating, wherein the surface coating and the photosensitive material, before or after curing, are soluble in a first liquid.

The photosensitive material is typically present on a substrate, and is generally in the form of a layer on the substrate. The substrate is typically planar, being e.g. in the form of a board, sheet or film. A layer of photosensitive material may be provided on one or both major faces of a planar substrate, with the same or different photosensitive materials on the two sides. The photosensitive material typically covers in uninterrupted manner all or a substantial portion of a substrate surface.

The substrate may be made of a wide range of materials including fibreglass, glass, semiconductors, metals, plastics materials, etc. including, e.g., polyethylene terephthalate (PET), polycarbonate, polyethylene-naphthalate (PEN).

The term “substrate” is used to refer to the material below the photosensitive material and may be made up of several layers. For example, the substrate may comprise a core substrate material, e.g. of plastics materials, with one or more coatings to modify its surface properties, such as, but not limited to, adhesion, surface tension, chemical resistance. The substrate might have thereon components and/or previously defined features. For example, the substrate might have thereon conductive, semiconductive, resistive, capacitive, inductive or optical materials defined into discrete components and/or as uninterrupted layers.

The term “photosensitive material” is used to mean a material which gives rise to a chemical or physical change in a curing reaction when exposed to electromagnetic radiation of one or more particular wavelengths, e.g. from a specific region of the electromagnetic spectrum. Such radiation is referred to herein as curing radiation and is usually UV, visible, infra red, electron beam radiation, or a combination thereof. The resulting radiation-induced change may be due to the generation of reactive chemical species via absorption of radiation (e.g. the generation of free radicals leading to polymerisation or the fission of chemical bonds in a polymer leading to increased solubility). This radiation-induced change may alternatively be a radiation induced physical change (e.g. an optically induced change of conformation in a polymer chain leading to increased free volume and a resulting expansion of the material). The radiation-induced change (or curing reaction) typically results in a change of solubility, as discussed above.

Photosensitive materials are well known, and a wide range of suitable photosensitive materials are readily available commercially. These include photosensitive monomers, oligomers and polymers, e.g. acrylate materials. The photosensitive material typically includes a photoinitiator, with suitable materials being well known in the art.

The photosensitive material may be a negative acting material, being rendered insoluble to developing medium by the action of curing radiation, which is therefore developed to form the negative image of the opaque regions of a photomask. Alternatively, the photosensitive material may be a positive acting material, being solubilised by exposure to curing radiation, and therefore forming a copy of the opaque regions of a photomask.

In certain embodiments, the photosensitive material is insoluble in water and is selectively soluble (in either cured or uncured condition but not both) in one or more organic solvents or mixtures thereof. Such solvent(s) can therefore constitute the first liquid, and be used as a developing medium. Suitable solvent(s) for this purpose can be readily determined for any particular photosensitive material.

In certain embodiments, the photosensitive material is insoluble in a non-alkaline solution and is selectively soluble (in either cured or uncured condition but not both) in an alkaline solution. An alkaline solution can therefore constitute the first liquid, and be used as a developing medium.

In certain embodiments, the photosensitive material is insoluble in an alkaline solution and is selectively soluble (in either cured or uncured condition but not both) in a non-alkaline solution. A non-alkaline solution can therefore constitute the first liquid, and be used as a developing medium.

In certain embodiments, the photosensitive material is insoluble in an acidic solution and is selectively soluble (in either cured or uncured condition but not both) in a neutral solution. A neutral solution can therefore constitute the first liquid, and be used as a developing medium.

In certain embodiments, the photosensitive material is insoluble in one or more organic solvents or mixtures thereof and is selectively soluble (in either cured or uncured condition but not both) in a primarily aqueous solution. A primarily aqueous solution can therefore constitute the first liquid, and be used as a developing medium.

In certain embodiments, the photosensitive material is selectively soluble (in either cured or uncured condition but not both) in a first one or more organic solution(s) or mixtures thereof and is insoluble in a different (second) one or more organic solution(s) or mixtures thereof. The first organic solution(s) can therefore constitute the first liquid and be used as a developing medium.

The surface coating may be intended to perform one or more of a number of functions. For example, the coating may modify the properties or performance of the underlying photosensitive material, e.g. by acting as an optical filter. Typically, the surface coating performs a protective function, to protect the photosensitive material or other components with which the structure is to be used, such as a photomask. For example, the surface coating may function as an oxygen barrier and/or a physical barrier. For instance, the photosensitive material may be slightly tacky before curing and provision of a non-tacky surface coating can prevent the photosensitive material sticking to or damaging a photomask, and can also facilitate storage of the substrate(s) coated with the photosensitive material, e.g. as stacked sheets or in a roll. The surface coating is typically in the form of an inert coating.

The surface coating should be transparent to curing radiation. 100% transparency is not required, provided sufficient radiation is transmitted to enable the photosensitive material to function, and the term “transparent” in this context should be interpreted accordingly. In certain embodiments the surface coating preferably transmits at least 50%, more preferably at least 60%, 70%, 80% or 90% of curing radiation.

In certain embodiments the surface coating performs the function of an attenuator of the curing radiation so that the underlying photosensitive material receives a selectable amount of curing radiation incident on the surface coating.

In certain embodiments the surface coating performs the function of a filter to the curing radiation so that the underlying photosensitive material receives certain wavelengths of the curing radiation incident on the surface coating.

In certain embodiments the surface coating performs the function of an attenuator and a filter to the curing radiation so that the underlying photosensitive material receives a selectable amount and/or certain wavelengths of the curing radiation incident on the surface coating.

The coating material is selected having regard to the intended function of the surface coating. Typically the coating material comprises film-forming polymer materials e.g. of polyester, acrylic polymers and copolymers such as styrene acrylic polymers. Such materials are commercially available as aqueous dispersions of small particles, typically of sub micron size, or aqueous emulsions, with water thus constituting the second liquid. Photosensitive materials, e.g. as discussed above, are commonly insoluble in water. Examples of commercially available aqueous dispersions include Eastek 1100 (Eastek is a Trade Mark) from Eastman, which is a polyester polymer supplied as an aqueous dispersion; Texicryl 13-809 (Texicryl is a Trade Mark) from Scott Bader, which is a styrene acrylic copolymer emulsion having a glass transition temperature (Tg) of 82° C. that produces films of high clarity, water resistance and heat resistance; Texicryl 13-813 from Scott Bader, which is a modified styrene acrylic copolymer emulsion that produces soft films of high gloss; Revacryl 815 (Revacryl is a Trade Mark) from Synthomer, which is a modified acrylic aqueous dispersion that produces glossy films; and Craymul 8500 (Craymul is a Trade Mark) from Cray Valley, which is an acrylic copolymer emulsion that produces soft films with good adhesion.

Such coating materials are soluble in a range of organic solvents, and such solvents can therefore be used as the first liquid, subject also to the requirement that the photosensitive materials are soluble therein, as discussed above.

The coating material can be applied to the photosensitive material by any convenient coating technique, as is well known in the art, including bar coating, roller coating, spray coating, spin coating, dip coating, gravure coating, gap coating, slot coating, etc.

After application, the dispersant liquid (typically water) is removed in a drying step, e.g. involving exposure to heat, to leave a surface coating.

The coating material may include optional additives, e.g. functioning to assist the application process or to modify the properties of the resulting coating. For example, the coating material may include one or more surfactants to facilitate the coating process. Additives such as wax may be included to impart slip properties to the coating, to facilitate mechanical handling e.g. through a roller system.

The additives need not be soluble in the first liquid, provided the integrity of the coating is disrupted by the first liquid sufficiently for the additives to be released and removed from the surface of the photosensitive material. Preferably such non-soluble additives in the coating material constitute not more than 70% by weight of the dried coated material, more preferably not more than 50%, 20% or 10% by weight of the dried coated material.

For any particular combination of coating material and photosensitive material, suitable first and second liquids are determined. The second liquid commonly comprises water, as discussed above, and the first liquid commonly comprises an organic solvent or mixture of solvents e.g. selected from solvents including dimethyl sulphoxide (DMSO), acetone, ethers, glycol ethers, e.g. diethylene glycol monoethyl ether (e.g. available as Carbitol (Carbitol is a Trade Mark)), etc.

In use, the coated substrate is exposed to curing radiation, typically in patternwise manner, so that the photosensitive material undergoes a radiation-induced curing reaction, resulting in a change of solubility.

A developing step is then carried out. This involves treatment with, e.g. immersion in, the first liquid, which functions as a developing medium. The first liquid removes the surface coating and selectively removes regions of photosensitive material (either only cured or uncured material, depending on whether the material is positive or negative acting), to leave a pattern of insoluble photosensitive material. It is thus not necessary to remove the surface coating prior to the developing step. The surface coating thus does not adversely affect functioning of the photosensitive material nor interfere with the curing and developing steps.

The invention also covers a method of processing a photosensitive structure in accordance with the invention, comprising exposing the photosensitive material to curing radiation, typically in patternwise manner; and treating the surface coating and the cured photosensitive material with the first liquid.

Exposure of the photosensitive material to curing radiation in patternwise manner to produce photopatterning may be performed in a number of ways, as is well known in the art. These include: by exposure through a mask or aperture which is imaged onto the photosensitive material or which is in contact with or in close proximity to the material; by exposing the photosensitive material to a small area of radiation which is then moved or scanned to form a desired pattern, e.g. by direct writing with a laser beam or electron beam or by the movement of an aperture plate; or by causing the radiation to form an intereference pattern by being diffracted onto the material, e.g. by a grating or slit, or by the projection of a hologram.

The resulting patterned photosensitive material may play many roles. For example, it may form an etch mask which protects the underlying material from a wet or dry etch process; it may form a template which prevents subsequent material from being deposited on the underlying material (e.g. by evaporation of metals or electroplating); and it may form a template on which a subsequent layer is formed (e.g. it may be a catalyst for electroless plating or a reactive layer onto which chemical or biological species may bind).

The invention finds particular application in the manufacture of items useful in the fields of electronics, optics and related disciplines.

The invention will be further described, by way of illustration, in the following examples and with reference to the accompanying drawings.

In the drawings;

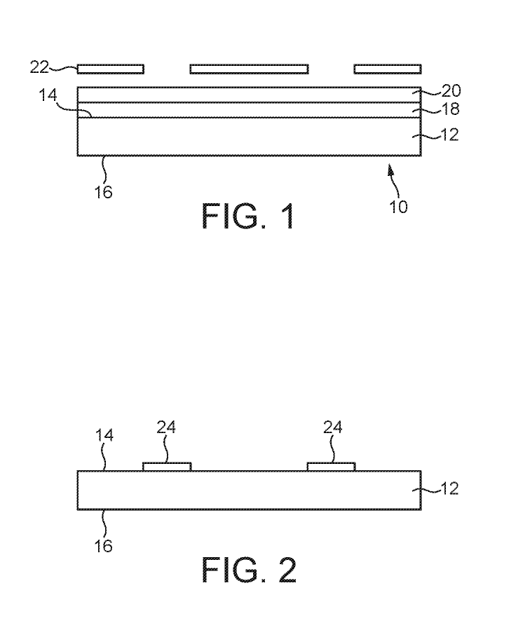

FIG. 1 is a schematic diagram illustrating a photopatternable structure in accordance with the invention, prior to patterning;

FIG. 2 is a view similar to FIG. 1 of the structure after patterning;

### DETAILED DESCRIPTION OF THE DRAWINGS

Referring to the drawings, FIG. 1 shows schematically (and not to scale) a photopatternable structure 10 in accordance with the invention, comprising a sheet of substrate material 12 having opposed major faces 14, 16. Face 14 bears a layer 18 of photosensitive material. A coating 20 of an inert, protective material is formed on top of the photosensitive layer 18, by application from a dispersion of the coating material.

In use, the face 14 of the structure is exposed in patterwise manner to curing radiation from a source (not shown) by the use of a mask represented at 22. Exposure to curing radiation results in reaction of only the exposed parts of the photosensitive layer 18 not covered by the mask, and alters the solubility properties of the photosensitive material with respect to a particular developing medium. In the illustrated embodiment, a negative acting photosensitive material is used that is converted from soluble to insoluble condition on exposure to curing radiation. Treatment with the developing medium under appropriate conditions results in selective removal of photosensitive material only in the regions not exposed to curing radiation, i.e. corresponding to the mask, leaving insoluble photocured material on the substrate only on those areas exposed to curing radiation, in pattern represented at 24 as shown in FIG. 2.

### EXAMPLES

### Example 1

Samples were prepared using a substrate film of PET-PMX726, 50μ HiFi Films. One major face of the substrate was coated with three layers, as follows.

1. A base layer was first coated onto the substrate and then cured using a 1 kW mercury lamp. This was to ensure a compatible surface energy for the subsequent coating.

2. An active layer of photosensitive material was then coated on top of the base layer and dried.

3. An inert top coat was then applied on top of the active layer. This dried to give a clear, non-tacky surface coating film which reduces oxygen inhibition during curing and protects the photomask from any damage from cure-on contamination from the active layer. The top coat is carefully formulated to be soluble in the developing medium to be used (DMSO/acetone) in the present case while being capable of being applied in the form of an aqueous dispersion which does not attack the underlying photosensitive material coating.

All coatings were applied by a 12μ drawdown bar and then dried on a hot plate at 50° C. for 5 minutes.

The three coating formulations were as follows:

1st layer (base layer)

| | Wt. % |
|---|---|
| Ethyl lactate | 92.3 |
| DPHA | 7 |
| Irgacure 907 | 0.7 |

Viscosity = 2.96 cPs (25° C.)
Dry thickness = 0.92μ

DPHA is a dipentaerythritol hexacrylate, a UV-curable hexafunctional monomer.

Irgacure 907 (Irgacure is a Trade Mark) is a photoinitiator.

2nd layer (active layer) is the same as 1st layer, but is simply dried, and not cured.

3rd layer (top coat layer)

| | Wt. % | |
|---|---|---|
| Deionised water | 72.12 | |
| Mowiol 4-88 (TM) | 6.12 | Polyvinyl alcohol |
| Eastek 1100 (TM) | 18.39 | Polyester aqueous dispersion |
| Hydrocer EC35 (TM) | 2.21 | Wax emulsion |
| Dowfax 2A1 (TM) | 0.36 | Surfactant |
| Surfadone LP100 (TM) | 0.50 | Surfactant |
| Novec FC4430 (TM) | 0.30 | Fluorosurfactant |

Dry thickness = 1.69μ

The coated side of the substrate was then exposed to UV light using a 1 kW mercury lamp, for 5 seconds at 20 mW/cm², through a chrome-on-glass photomask.

After exposure the sample were developed. This was carried out using DMSO/acetone (50/50). The sample was immersed for 5 minutes in DMSO/acetone, rinsed with acetone from wash bottle, rinsed with deionised (DI) water from wash bottle, and blown dry with an air gun. This developing step selectively removes unexposed regions of the active layer. As noted above, the top coat is soluble in DMSO/acetone and so is also removed in this step.

### Example 2

The photosensitive material in Example 1 may be turned into a catalyst for additive electroless plating by the addition of a catalytic material such as colloidal palladium.

A polyvinyl pyrrolidone (PVP)-based colloid was added to the photosensitive formulation described in Example 1 and processed using the same procedure. Exposure time was increased to 10 seconds to ensure thorough curing of the material. Developing was performed as in Example 1. During the DMSO/acetone stage, most of the unexposed catalyst material could be seen washing off to reveal the pattern from the photomask. Copper plating was carried out in an Enthone Entrace EC 5005 bath at standard conditions. It was found that plating initiation could be more rapid if a dimethyl aminoborane (DMAB) pre-dip was used (1.6% solution at room temperature for 2 minutes) before plating. In either case, samples were plated for 3-4 minutes to give a continuous and lustrous copper film.

Photosensitive Catalyst formulation:

| | Wt. % |
|---|---|
| Ethyl lactate | 72.3 |
| DPHA | 7 |
| Irgacure 907 | 0.7 |
| Pd/PVP K15 colloid | 20 |

Formulation of Pd/PVP K15 colloid:

| | Wt. % |
|---|---|
| Ethyl lactate | 91 |
| Palladium acetate | 4.5 |
| PVP K15 | 4.5 |

1. A method of applying a coating material to a photosensitive material to form a surface coating, wherein the photosensitive material, before or after curing, and the surface coating are soluble in a first liquid, the method comprising applying the coating material as a dispersion in a second liquid in which the photosensitive material is insoluble before curing.

2. A method according to claim 1, wherein the first liquid comprises one or more organic solvents.

3. A method according to claim 2, wherein the organic solvent is selected from the group consisting of dimethyl sulphoxide, acetone, ethers and glycol ethers.

4. A method according to claim 1, wherein the second liquid comprises water.

5. A method according to claim 1, wherein the surface coating comprises an inert coating.

6. A method according to claim 1, wherein the coating material comprises a film-forming polymer.

7. A method according to claim 6, wherein the polymer is selected from the group consisting of polyesters, acrylic polymers and copolymers.

8. A method according to claim 1, wherein the coating material includes comprises one or more surfactants.

9. A method according to claim 1, wherein the coating material comprises one or more additives that are not soluble in the first liquid.

10. A method according to claim 9, wherein the one or more non-soluble additives constitute not more than 70% by weight of the surface coating.

11. A photosensitive structure comprising a photosensitive material having a surface coating, wherein the surface coating and the photosensitive material, before or after curing, are soluble in a first liquid.

12. A method of processing a photosensitive structure according to claim 11, comprising exposing the photosensitive material to curing radiation; and treating the surface coating and the cured photosensitive material with the first liquid.
